(19) United States
(12) Patent Application Publication
(10) Pub. No.: US 2026/0190657 A1
(43) Pub. Date: Jul. 2, 2026

(54) DISPLAY APPARATUS

(71) Applicant: LG Display Co., Ltd., Seoul (KR)

(72) Inventor: Wanhee Lee, Cheonan-si (KR)

(21) Appl. No.: 19/223,707

(22) Filed: May 30, 2025

(30) Foreign Application Priority Data
Dec. 26, 2024 (KR) 10-2024-0197288

(51) Int. Cl. H10K 59/124; H10K 59/127; H10K 59/131; H10K 59/80; H10K 77/10; H10K 102/00

(52) U.S. Cl. CPC H10K 59/124; H10K 59/127; H10K 59/131; H10K 59/8794; H10K 77/111; H10K 2102/311

(57) ABSTRACT

In a display device, a flexible resin layer is disposed on a substrate in a bendable area, a first planarization layer is disposed on the flexible resin layer, a plurality of data lines is disposed on the first planarization layer, a second planarization layer is disposed on the plurality of data lines, wherein a real neutral plane and a target neutral plane are positioned in the second planarization layer in the bendable area, wherein in each of the real neutral plane and the target neutral plane, a compressive force and a tensile force counteract against each other. The display device can help mitigate a line necking or a bending crack from occurring in the bendable area of the display panel.

### CROSS-REFERENCE TO RELATED APPLICATION

Pursuant to 35 U.S.C. § 119(a), this application claims the benefit of an earlier filing date and right of priority to Korean Patent Application No. 10-2024-0197288 filed on Dec. 26, 2024 in the Korean Intellectual Property Office, the contents of which are incorporated by reference herein in their entirety.

### TECHNICAL FIELD

The present disclosure generally relates to a display device.

### BACKGROUND

An electroluminescent display device represented by an organic light emitting display device is a self-luminous display device. Unlike a liquid crystal display device, a separate light source is not required in the electroluminescent display device, so that the electroluminescent display device may be manufactured in a lightweight and thin shape. In addition, the electroluminescent display device is advantageous in terms of power consumption due to low voltage operation, and is excellent in color rendering, response speed, viewing angle, and Contrast Ratio (CR), and thus is expected to be used in various fields.

The electroluminescent display device is encapsulated with glass, metal, or film to prevent the inflow of moisture or oxygen into the electroluminescent display device from the outside, thereby preventing oxidation of an emission layer or an electrode, and protecting the electroluminescent display device from a mechanical or physical impact applied from the outside.

Recently, a flexible electroluminescent display device capable of maintaining display performance even when being bent by applying a flexible substrate made of a flexible material such as plastic thereto has been provided. In this regard, there is an effort to reduce an bezel area by bending the non-display area NDA at one side of the flexible substrate in order to reduce the bezel area while securing an area for a line and a driving circuit. Such a display device is also referred to as a bezel bending display device.

### SUMMARY

A display device according to an implementation of the present disclosure includes: a substrate including a display area, a non-display area, and a bendable area disposed in the non-display area; and a display panel disposed on the substrate, wherein the display panel has one side edge that is disposed in the bendable area and is bent in a backward direction to curve back towards the display area with a predetermined curvature, wherein the display panel includes: a flexible resin layer disposed on the substrate in the bendable area; a first planarization layer disposed on the flexible resin layer in the bendable area; a plurality of data lines disposed on the first planarization layer in the bendable area; a second planarization layer disposed on the plurality of data lines and the first planarization layer in the bendable area; and a passivation layer disposed on the second planarization layer in the bendable area, wherein a real neutral plane and a target neutral plane are positioned in the second planarization layer in the bendable area, wherein in each of the real neutral plane and the target neutral plane, a compressive force and a tensile force counteract against each other.

Details of other implementations are included in the detailed description and drawings.

The solutions for achieving the purposes according to implementations of the present disclosure are not limited to the above-mentioned solutions, and other solutions not mentioned above will be clearly understood by those skilled in the art from following descriptions.

### BRIEF DESCRIPTION OF DRAWINGS

FIG. 1 is a plan view of a display device according to an implementation of the present disclosure.

FIG. 2 is a cross-sectional view of a display device according to an implementation of the present disclosure taken along a line A-A′ of FIG. 1.

FIG. 3 is an enlarged view of a portion B of FIG. 2 in a display device according to an implementation of the present disclosure.

FIG. 4 is a cross-sectional view of a portion C of FIG. 3 in a display device according to an implementation of the present disclosure as compared to another structure.

FIG. 5 is an example diagram illustrating presence or absence of bending necking under presence or absence of a bendable protective layer in a display panel according to an implementation of the present disclosure.

FIG. 6 is a diagram illustrating a tensile force, a compressive force, and a neutral plane when one bendable material is made of one material according to an implementation of the present disclosure.

FIG. 7 is a diagram illustrating a tensile force, a compressive force, and a neutral plane when one bendable material is made of a plurality of materials according to an implementation of the present disclosure.

FIG. 8 is a diagram illustrating a neutral plane when a plurality of bendable materials are attached to each other by a flexible material according to an implementation of the present disclosure.

### DETAILED DESCRIPTIONS

The present disclosure relates to a display device that can help mitigate the occurrence of cracks in a bendable area of the display.

In a display panel, a protective layer (Micro Coating Layer) can be applied to a bendable area so that the tensile force is not applied to a data line SD in bending the bezel area.

However, in scenarios where the modulus of the substrate is large (e.g., 5 Gpa), the neutral plane (which is not subjected to stress because the compressive force and the tensile force counteract against each other in the neutral plane) cannot be moved to a target position.

Accordingly, the tensile stress acts on a layer in which the data line is disposed in the bendable area, and thus there is a problem in that the line necking or the bending crack occurs.

In order to solve the above-described problems, implementations of the present disclosure provide a display device that can help mitigate problems of line necking or bending crack from occurring in the bendable area of the display panel.

For example, implementations of the present disclosure provide a display device capable of preventing the line necking or the bending crack by additionally disposing a soft resin layer on a substrate in a bendable area of a display panel, which can help adjust a position of the neutral plane.

Purposes according to the present disclosure are not limited to the above-mentioned purpose. Other purposes and advantages according to the present disclosure that are not mentioned may be understood based on following descriptions, and may be more clearly understood based on implementations according to the present disclosure. Further, it will be easily understood that the purposes and advantages according to the present disclosure may be realized using means shown in the claims or combinations thereof.

According to an implementation of the present disclosure, the flexible resin layer is disposed between the substrate and the planarization layer in the bendable area to protect the display panel, and the position of the neutral plane is adjusted based on the flexible resin layer, such that the same effect comparable to the effect obtained by removing the substrate in terms of the neutral plane in the conventional case may be obtained.

In addition, according to an implementation of the present disclosure, there is an effect of removing the tensile force applied to a layer in which the data line is disposed in the bendable area.

In addition, according to an implementation of the present disclosure, the tensile force applied to the layer in which the data line is disposed in the bendable area is removed, thereby preventing the line necking or bending crack from occurring.

In addition, according to an implementation of the present disclosure, there is an effect of removing the protective layer MCL for the display panel DP in the bendable area BA, thereby reducing a manufacturing (production) cost of the display device and simplifying a structure thereof.

In addition, according to an implementation of the present disclosure, the occurrence of cracks in the bendable area BA may be prevented to improve defects of the display panel, thereby improving the lifespan of the display device.

In addition, the display device according to an implementation of the present disclosure can be manufactured and produced without the need to include a separate protective layer for the display panel in the bendable area, thereby reducing a harmful/regulated material for production.

In addition, according to the implementation of the present disclosure, the occurrence of the defect in the product may be prevented such that the quality of the product is improved, and reliability is secured accordingly, thereby realizing a narrow bezel.

Effects of the present disclosure are not limited to the effects mentioned above, and other effects not mentioned will be clearly understood by those skilled in the art from the description as set forth below.

In addition to the above effects, specific effects of the present disclosure are described together while describing specific details for carrying out the present disclosure.

Advantages and features of the present disclosure, and a method of achieving the advantages and features will become apparent with reference to implementations described later in detail together with the accompanying drawings. However, the present disclosure is not limited to the implementations as disclosed under, but may be implemented in various different forms. Thus, these implementations are set forth only to make the present disclosure complete, and to completely inform the scope of the present disclosure to those of ordinary skill in the technical field to which the present disclosure belongs, and the present disclosure is only defined by the scope of the claims.

For simplicity and clarity of illustration, elements in the drawings are not necessarily drawn to scale. The same reference numbers in different drawings represent the same or similar elements, and as such perform similar functionality. Further, descriptions and details of well-known steps and elements are omitted for simplicity of the description. Furthermore, in the following detailed description of the present disclosure, numerous specific details are set forth in order to provide a thorough understanding of the present disclosure. However, it will be understood that the present disclosure may be practiced without these specific details. In other instances, well-known methods, procedures, components, and circuits have not been described in detail so as not to unnecessarily obscure aspects of the present disclosure. Examples of various implementations are illustrated and described further below. It will be understood that the description herein is not intended to limit the claims to the specific implementations described. On the contrary, it is intended to cover alternatives, modifications, and equivalents as may be included within the spirit and scope of the present disclosure as defined by the appended claims.

A shape, a size, a ratio, an angle, a number, etc. disclosed in the drawings for illustrating implementations of the present disclosure are illustrative, and the present disclosure is not limited thereto.

The terminology used herein is directed to the purpose of describing particular implementations only and is not intended to be limiting of the present disclosure. As used herein, the singular constitutes “a” and “an” are intended to include the plural constitutes as well, unless the context clearly indicates otherwise. It will be further understood that the terms “comprise”, “comprising”, “include”, and “including” when used in this specification, specify the presence of the stated features, integers, operations, elements, and/or components, but do not preclude the presence or addition of one or more other features, integers, operations, elements, components, and/or portions thereof. As used herein, the term “and/or” includes any and all combinations of one or more of associated listed items. Expression such as “at least one of” when preceding a list of elements may modify the entire list of elements and may not modify the individual elements of the list. In interpretation of numerical values, an error or tolerance therein may occur even when there is no explicit description thereof.

In addition, it will also be understood that when a first element or layer is referred to as being present “on” a second element or layer, the first element may be disposed directly on the second element or may be disposed indirectly on the second element with a third element or layer being disposed between the first and second elements or layers. It will be understood that when an element or layer is referred to as being “connected to”, or “coupled to” another element or layer, it may be directly connected to, or coupled to the other element or layer, or one or more intervening elements or layers may be present therebetween. In addition, it will also be understood that when an element or layer is referred to as being “between” two elements or layers, it may be the only element or layer between the two elements or layers, or one or more intervening elements or layers may also be present.

Further, as used herein, when a layer, film, area, plate, or the like is disposed “on” or “on top” of another layer, film, area, plate, or the like, the former may directly contact the latter or still another layer, film, area, plate, or the like may be disposed between the former and the latter. As used herein, when a layer, film, area, plate, or the like is directly disposed “on” or “on top” of another layer, film, area, plate, or the like, the former directly contacts the latter and still another layer, film, area, plate, or the like is not disposed between the former and the latter. Further, as used herein, when a layer, film, area, plate, or the like is disposed “beneath” or “under” another layer, film, area, plate, or the like, the former may directly contact the latter or still another layer, film, area, plate, or the like may be disposed between the former and the latter. As used herein, when a layer, film, area, plate, or the like is directly disposed “beneath” or “under” another layer, film, area, plate, or the like, the former directly contacts the latter and still another layer, film, area, plate, or the like is not disposed between the former and the latter.

In descriptions of temporal relationships, for example, temporal precedent relationships between two events such as “after”, “subsequent to”, “before”, etc., another event may occur therebetween unless “directly after”, “directly subsequent” or “directly before” is not indicated.

When a certain implementation may be implemented differently, a function or an operation specified in a specific block may occur in a different order from an order specified in a flowchart. For example, two blocks in succession may be actually performed substantially concurrently, or the two blocks may be performed in a reverse order depending on a function or operation involved.

It will be understood that, although the terms “first”, “second”, “third”, and so on may be used herein to describe various elements, components, areas, layers and/or periods, these elements, components, areas, layers and/or periods should not be limited by these terms. These terms are used to distinguish one element, component, area, layer or section from another element, component, area, layer or period. Thus, a first element, component, area, layer or section as described under could be termed a second element, component, area, layer or period, without departing from the spirit and scope of the present disclosure.

When an implementation may be implemented differently, functions or operations specified within a specific block may be performed in a different order from an order specified in a flowchart. For example, two consecutive blocks may actually be performed substantially simultaneously, or the blocks may be performed in a reverse order depending on related functions or operations.

The features of the various implementations of the present disclosure may be partially or entirely combined with each other, and may be technically associated with each other or operate with each other. The implementations may be implemented independently of each other and may be implemented together in an association relationship.

In interpreting a numerical value, the value is interpreted as including an error range unless there is no separate explicit description thereof.

Unless otherwise defined, all terms including technical and scientific terms used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

As used herein, “implementations,” “examples,” “aspects, and the like should not be construed such that any aspect or design as described is superior to or advantageous over other aspects or designs.

Further, the term ‘or’ means ‘inclusive or’ rather than ‘exclusive or’. That is, unless otherwise stated or clear from the context, the expression that ‘x uses a or b’ means any one of natural inclusive permutations.

The terms used in the description below have been selected as being general and universal in the related technical field. However, there may be other terms than the terms depending on the development and/or change of technology, convention, preference of technicians, etc. Therefore, the terms used in the description below should not be understood as limiting technical ideas, but should be understood as examples of the terms for illustrating implementations.

Further, in a specific case, a term may be arbitrarily selected by the applicant, and in this case, the detailed meaning thereof will be described in a corresponding description period. Therefore, the terms used in the description below should be understood based on not simply the name of the terms, but the meaning of the terms and the contents throughout the Detailed Descriptions.

In description of flow of a signal, for example, when a signal is delivered from a node A to a node B, this may include a case where the signal is transferred from the node A to the node B through another node unless a phrase ‘immediately transferred’ or ‘directly transferred’ is used.

Throughout the present disclosure, “A and/or B” means A, B, or A and B, unless otherwise specified, and “C to D” means C inclusive to D inclusive unless otherwise specified.

“At least one” should be understood to include any combination of one or more of listed components. For example, at least one of first, second, and third components means not only a first, second, or third component, but also all combinations of two or more of the first, second, and third components.

As used herein, the term “display device” may include, in a narrow sense, a display device including a liquid crystal module (LCM), an organic light-emitting diode (OLED) module, or a quantum dot (QD) module including a display panel and a driver for driving the display panel. Moreover, the display device may include, in a broad sense, a laptop computer, a television, a computer monitor, an automotive device or an equipment display for a vehicle, a set electronic device, a set device or a set device including a complete product or a final product including the LCM, the OLED module, or the QD module.

Therefore, the display device in accordance with the present disclosure may include, in the narrow sense, a display device itself including, for example, the LCM, the OLED module, QD module, etc., and may include, in a broad sense, the set device as an application product or an end-user device including a complete product or a final product including the LCM, the OLED module, or the QD module.

Moreover, in some cases, the LCM, OLED module, or QD module composed of the display panel and the driver may be expressed as “display device” in a narrow sense. The electronic device as a complete product including the LCM, OLED module or QD module may be expressed as “set” device” in a broad sense. For example, the display device in the narrow sense may include a display panel such as a liquid crystal panel, an organic light-emitting display panel, or a quantum dot display panel, and a source PCB as a controller for driving the display panel. The set device in the broad sense may include a display panel such as a liquid crystal panel, an organic light-emitting display panel, or a quantum dot display panel, a source PCB as a controller for driving the display panel, and a set PCB as a set controller that is electrically connected to the source PCB and controls the set device.

As used herein, the display panel may be of any type of the display panels such as a liquid crystal display panel, an organic light emitting diode (OLED) display panel, a quantum dot (QD) display panel, and an electroluminescent display panel, etc. The display panel used in the disclosure may not be limited to a specific display panel including a flexible substrate for the OLED display panel and an underlying back plate support structure and having a bendable bezel. Moreover, the display panel used in the display device according to an implementation of the present disclosure is not limited to a shape or a size of the display panel.

Hereinafter, implementations of the present disclosure will be described using the attached drawings. A scale of each of components as shown in the drawings is different from an actual scale thereof for convenience of illustration, and therefore, the present disclosure is not limited to the scale as shown in the drawings.

As used herein, a first direction, a second direction, and a third direction, or an X-axis direction, a Y-axis direction, and a Z-axis direction should not be interpreted only as having a geometric relationship with each other in which the first direction, the second direction, and the third direction are perpendicular to each other or the X-axis direction, the Y-axis direction, and the Z-axis direction are perpendicular to each other, but may be interpreted as having a geometric relationship with each other in which the first direction, the second direction, and the third direction interest each other at an angle other than 90 degrees or the X-axis direction, the Y-axis direction, and the Z-axis direction are interest each other at an angle other than 90 degrees within a range in which a configuration of the present disclosure may work functionally.

Hereinafter, a display device according to an implementation of the present disclosure will be described with reference to the drawings.

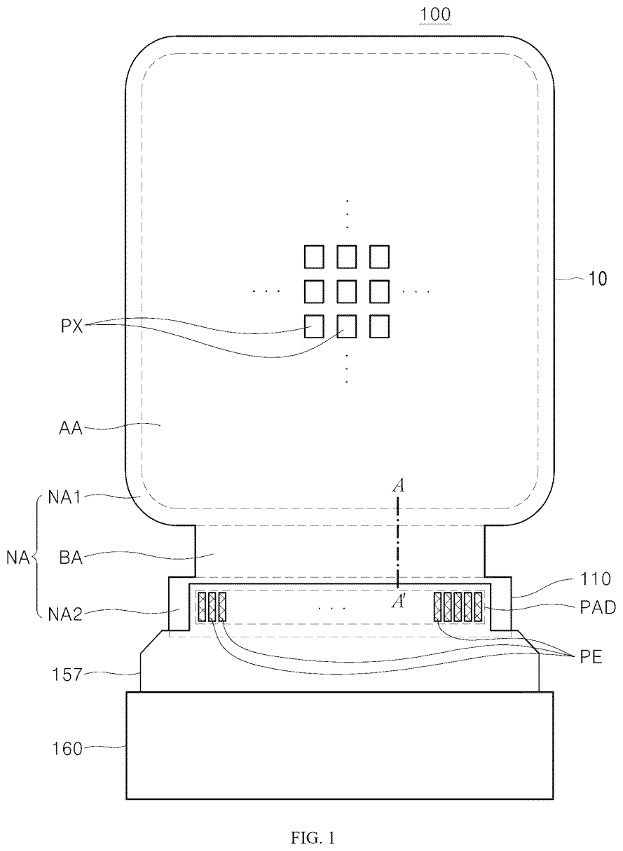

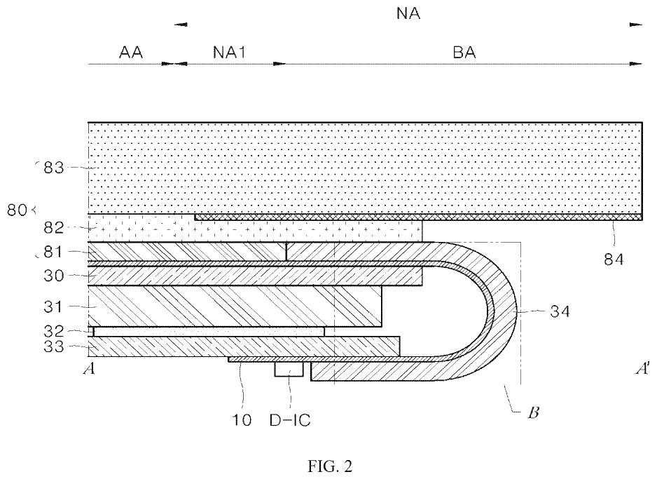

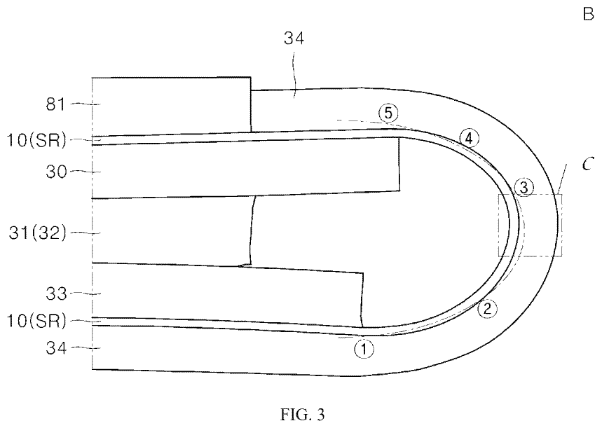

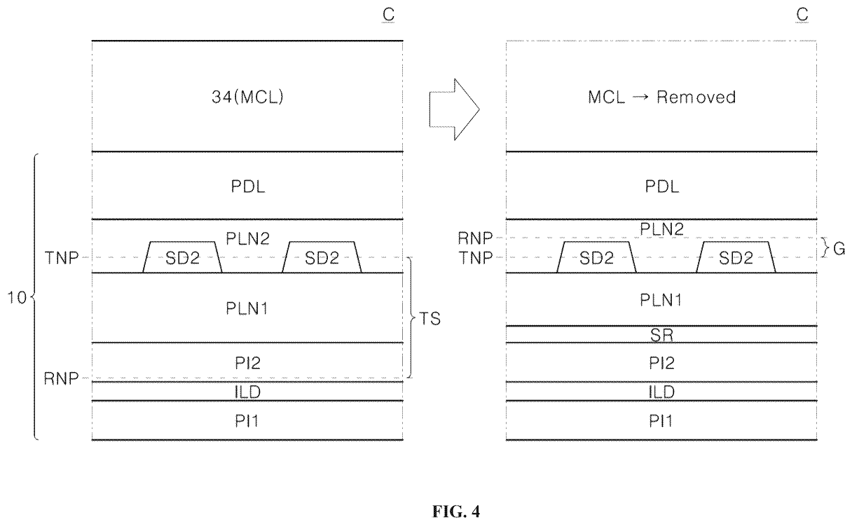

FIG. 1 is a plan view of a display device according to an implementation of the present disclosure. FIG. 2 is a cross-sectional view of a display device according to an implementation of the present disclosure taken along a line A-A′ of FIG. 1. FIG. 3 is an enlarged view of a portion B of FIG. 2 in a display device according to an implementation of the present disclosure. FIG. 4 is a cross-sectional view illustrating a portion C of FIG. 3 in a display device according to an implementation of the present disclosure as compared with a conventional structure.

Referring to FIGS. 1 to 4, a display device 100 according to an implementation of the present disclosure may include a substrate 110 including a display area AA, a bendable area BA, and a non-display area NA, and a display panel 10 disposed on the substrate 110.

In addition, the display device 100 may further include a flexible circuit board 157 connected to the substrate 110 and a printed circuit board 160 connected to the flexible circuit board 157.

One side edge of the display panel 10 may be disposed in the bendable area BA and may be bent in a backward direction to curve back towards the display area AA with a predetermined curvature.

The substrate 110 may be a member supporting other components of the display device 100. The substrate 110 may be made of an insulating material. For example, the substrate 110 may be made of glass or resin. In addition, the substrate 110 may be made of a material having flexibility. For example, the substrate 110 may be made of a plastic material having flexibility, such as polyimide (PI). However, implementations of the present disclosure are not limited thereto.

The display panel 10 may display information, a video, and/or an image to be provided to a user. For example, the display panel 10 may include a display area AA and a non-display area NA. For example, the substrate 110 may include the display area AA and the non-display area NA. The distinction between the display area AA and the non-display area NA is applied not only to the substrate 110 but also to the display device 100.

The display area AA may be an area in which an image is displayed. The display area AA may include a plurality of pixels PX. Each of the plurality of pixels PX may be composed of a plurality of sub-pixels. A plurality of light-emitting elements may be disposed in each of the plurality of sub-pixels SP. A type of each of the plurality of light-emitting elements may vary according to a type of the display device 100. For example, when the display device 100 is an inorganic light-emitting display device, the light-emitting element may be a light-emitting diode (LED), a micro light-emitting diode (LED), or a mini light-emitting diode (LED). However, implementations of the present disclosure are not limited thereto.

The non-display area NA may be an area in which no image is displayed. Various lines and circuits for driving the plurality of pixels PX of the display area AA may be disposed in the non-display area NAA. For example, various wires and driving circuits may be mounted in the non-display area NA, and a pad PAD to which an integrated circuit, a printed circuit, etc. are connected may be disposed in the non-display area NA. However, implementations of the present disclosure are not limited thereto.

For example, the driving circuit may be a data driving circuit and/or a gate driving circuit. However, implementations of the present disclosure are not limited thereto. Wires to which a control signal for controlling the driving circuits is supplied may be disposed. For example, the control signal may include various timing signals including a clock signal, an input data enable signal, and synchronization signals. However, implementations of the present disclosure are not limited thereto. The control signal may be received through the pad PAD. For example, link lines for transmitting signals may be disposed in the non-display area NA. For example, driving components such as a flexible printed circuit board 157 and a printed circuit board 160 may be connected to the pad PAD.

According to the present disclosure, the non-display area NA may include a first non-display area NA1, a bendable area BA, and a second non-display area NA2. For example, the first non-display area NA1 may be an area surrounding at least a portion of the display area AA. The bendable area BA is an area extending from at least one of a plurality of sides of the first non-display area NA1 and may be a bendable area. The second non-display area NA2 may be an area extending from the bendable area BA, and the pad PAD may be disposed in the second non-display area. For example, the bendable area BA may be in a bent state, and the remaining area of the substrate 110 except for the bendable area BA may be in a flat state. In this case, as the bendable area BA is bent, the second non-display area NA2 may be located on a rear surface of the display area AA. However, implementations of the present disclosure are not limited thereto.

The display area AA of the substrate 110 or the display device 100 may be formed in various shapes according to the designs of the display device 100. For example, the display area AA may be formed in a rectangular shape having four corners of a round shape. However, implementations of the present disclosure are not limited thereto. In another example, the display area AA may be formed in a rectangular shape in which four corners have a right angle or a circular shape. However, implementations of the present disclosure are not limited thereto.

According to the present disclosure, a width of the second non-display area NA2 in which a plurality of pad electrodes PE are disposed may be greater than a width of the bendable area BA in which only a plurality of link lines are disposed. In addition, the width of the display area AA in which the plurality of sub-pixels are disposed may be greater than the width of the bendable area BA in which only the plurality of link lines are disposed. Although the width of the bendable area BA is illustrated as being smaller than the width of the remaining area of the substrate 110 in the drawing, a shape of the substrate 110 including the bendable area BA is merely an example, and implementations of the present disclosure are not limited thereto.

The flexible circuit board 157 and the printed circuit board 160 may be disposed under the display panel 10. The flexible circuit board 157 and the printed circuit board 160 may be disposed at least at one edge of the display panel 10. However, implementations of the present disclosure are not limited thereto. One side of the flexible circuit board 157 may be attached to the display panel 10 and the other side thereof may be attached to the printed circuit board 160. However, implementations of the present disclosure are not limited thereto. The flexible circuit board 157 may be a flexible film. However, implementations of the present disclosure are not limited thereto.

The pad PAD including a plurality of pad electrodes PE may be disposed in the second non-display area NA2. A driving component including one or more flexible circuit boards (or flexible films) 157 and the printed circuit board 160 may be attached or bonded to the pad PAD. The plurality of pad electrodes PE of the pad PAD may be electrically connected to one or more flexible circuit boards (or flexible films) 157, and may transmit various signals (or power) from the printed circuit board 160 and the flexible circuit boards (or flexible films) 157 to the plurality of pixel driving circuits (not shown) of the display area AA.

The flexible circuit board (or flexible film) 157 may be a film in which various components are disposed on a flexible base film. For example, a driving IC such as a gate driver IC or a data driver IC may be disposed on the flexible circuit board (or flexible film) 157. However, implementations of the present disclosure are not limited thereto. The driving IC DT may be a component that processes data for displaying an image and a driving signal. The driving IC DT may be disposed in a manner such as a Chip On Glass (COG), a Chip On Film (COF), or a Tape Carrier Package (TCP) according to a mounted manner. However, implementations of the present disclosure are not limited thereto. The flexible circuit board (or flexible film) 157 may be attached or bonded to the plurality of pad electrodes PE via a conductive adhesive layer. However, implementations of the present disclosure are not limited thereto.

The printed circuit board 160 may be electrically connected to one or more flexible circuit boards (or flexible films) 157 and may be a component that supplies a signal to the driving IC. The printed circuit board 160 may be disposed on one side of the flexible circuit board (or flexible film) 157 so as to be electrically connected to the flexible circuit board (or flexible film) 157. Various components for supplying various signals to the driving IC may be disposed on the printed circuit board 160. For example, various components such as a timing controller, a power supply unit, a memory, or a processor may be disposed on the printed circuit board 160. For example, the printed circuit board 160 may include a power management integrated circuit (PMIC). However, implementations of the present disclosure are not limited thereto.

Although not shown, the printed circuit board 160 may include at least one hole. However, implementations of the present disclosure are not limited thereto. An internal component for sensing ambient light or temperature that may be provided to the plurality of sensors may be disposed in an area corresponding to the at least one hole. For example, the internal component may include an ALS (Ambient light sensor), a temperature sensor, etc. However, implementations of the present disclosure are not limited thereto. For example, the hole may be a transmission hole or the like. However, implementations of the present disclosure are not limited thereto.

Referring to FIG. 4, the substrate 110 of a display device according to an implementation of the present disclosure may include a first substrate PI1 and a second substrate PI2, and an intermediate layer ILD between the first substrate PI1 and the second substrate PI2.

Each of the first substrate PI1 and the second substrate PI2 may be made of at least one of polyimide, polyethersulfone, polyethylene terephthalate, and polycarbonate. However, implementations of the present disclosure are not limited thereto. When the substrate 110 is made of a plastic material, a process of manufacturing a display device may be performed in a state in which a support substrate made of glass is disposed under the substrate 110, and the support substrate may be released after the process of manufacturing the display device is completed. In addition, after the support substrate is released, a back plate (or a plate) for supporting the substrate may be disposed under the substrate. When the substrate is made of a plastic material, moisture may penetrate the substrate and may be transmitted to the thin-film transistor TFT or the light-emitting element layer, thereby deteriorating the performance of the display device. The display device according to an implementation of the present disclosure may include two substrates, that is, the first substrate PI1 and the second substrate PI2 made of a plastic material in order to prevent the performance of the display device from being deteriorated due to the moisture permeation. In addition, forming the intermediate layer ILD which is embodied as an inorganic film between the first substrate PI1 and the second substrate PI2 may allow the moisture to be prevented from penetrating the substrate, thereby improving the performance reliability of the product. The intermediate layer ILD may be made of an inorganic material. For example, the intermediate layer ILD may be composed of a single layer made of silicon nitride (SiNx) or silicon oxide (SiOx), or of multiple layers made thereof. However, implementations of the present disclosure are not limited thereto.

The display device formed on the substrate 110 may include a plurality of areas. In the present disclosure, the display area AA and the non-display area NA are defined. However, implementations of the present disclosure are not limited thereto.

Referring to FIG. 2, an polarizing layer 81 may be disposed on the display panel 10, an adhesive layer 82 may be disposed on the polarizing layer 81, and a cover member 83 may be disposed on the adhesive layer 82. FIG. 2 schematically illustrates a cross-sectional view of an area in which the display panel 10 has been bent in the display device 100.

The polarizing layer 81 may include a polarizing film. Implementations of the present disclosure are not limited thereto. The polarizing layer 81 may prevent or reduce light generated from an external light source from entering the display panel 10 and affecting the light-emitting element LD.

The cover member 83 may be a member for protecting the display panel 10. The adhesive layer 82 may be disposed between the polarizing layer 81 and the cover member 83. The cover member 83 may be attached to the display panel 10 via the adhesive layer 82. The adhesive layer 82 may include an OCA (Optically clear adhesive), an OCR (Optically clear resin), a PSA (Pressure sensitive adhesive), or the like. However, implementations of the present disclosure are not limited thereto.

The display device 100 may further include first and second back plates 30 and 33 disposed on a rear surface of the display panel 10 in the display area AA. The first back plate 30 and the second back plate 33 supporting the display panel 10 may be attached to a lower surface of the display panel 10. The first back plate 30 may be disposed in the display area AA, and the second back plate 33 may be spaced apart from the first back plate 30 by a predetermined distance and may be disposed in a pad line area and an area of the data driver D-IC and the flexible circuit board 157.

Each of the first back plate 30 and the second back plate 33 may include at least one of polyimide (PI), polyethylene naphthalate (PEN), polyethylene terephthalate (PET), polymers, and combinations of the polymers.

The display panel 10 is bent in the area where the first back plate 30 and the second back plate 33 are spaced apart from each other, so that a lower surface of the first back plate 30 and a lower surface of the second back plate 33 may face each other.

The display panel 10 may include a first flat portion, a second flat portion facing the first flat portion, and a curved portion that extends from the first flat portion and is bent in a rear direction, and is positioned between the first flat portion and the second flat portion. The first and second back plates 30 and 33 may be positioned on the rear surfaces of the first and second flat portions, respectively.

The display device 100 may further include a fixing member 31 disposed on the rear surface of the first back plate 30, and an adhesive member 32 disposed between the fixing member 31 and the second back plate 33.

The fixing member 31 may be disposed under the first back plate 30. The fixing member 31 may include an adhesive and a heat dissipation sheet, and may include a metal layer capable of reflecting external light therefrom. However, implementations of the present disclosure are not limited thereto.

The fixing member 31 may be made of a metal material, or may include a composite heat dissipation sheet having a heat dissipation function, a grounding function, and a function of protecting the rear surface.

The adhesive member 32 for connecting the fixing member 31 and the second back plate 33 to each other may be disposed under the fixing member 31. The adhesive member 32 may be a double-sided tape, a double-sided foam adhesive tape, or a double-sided foam adhesive pad.

The display device 100 may further include a bendable protective layer 34 disposed on an outer surface of the bent portion of the display panel 10 in the bendable area BA. The bendable protective layer 34 may be disposed in the bendable area BA of the display panel 10. The bendable protective layer 34 may include a micro coating layer made of a resin-based material. The bendable protective layer 34 may include a polymer material to prevent moisture permeation into the bendable area BA.

A cover window 80 may be disposed on the display panel 10. The cover window 80 may include the polarizing layer 81, the adhesive layer 82, and the cover member 83.

An end of the cover member 83 may be disposed outwardly beyond an outer end of the bent portion of the display panel 10. The cover member 83 may include a black ink 84 applied to a portion thereof corresponding to the non-display area NA in order to prevent light leakage of the non-display area NA of the display panel 10. The black ink 84 may be, for example, a Black Matrix (BM) including a black material.

The data driver D-IC as a driving circuit may be disposed on a distal end of a rear surface of the bent portion of the display panel 10.

Referring to FIG. 3, the display panel 10 may include a soft resin SR therein. The display panel 10 may have a first point \textcircled{1} to a fifth point \textcircled{5} in the bendable area BA. The flexible resin layer SR may be disposed to extend along the first point \textcircled{1} to the fifth point \textcircled{5} in the bendable area BA of the display panel 10.

A structure of the third point \textcircled{3} in the bendable area BA of the display panel 10 may be represented as shown in FIG. 4. That is, FIG. 4 is a diagram illustrating a cross-sectional structure of the third point \textcircled{3} which is a portion C of FIG. 3 in the bendable area BA of the display panel 10 according to an implementation of the present disclosure. In the bendable area BA, the first point \textcircled{1} may be located at an end of a lower portion of the second back plate 33 in the bent state, and the fifth point \textcircled{5} may be located at an end of an upper portion of the first back plate 30 at the bent state. The third point \textcircled{3} may be located at a center of the display panel 10 in the bendable area BA in the bent state, the second point \textcircled{2} may be located between the first point \textcircled{1} and the third point \textcircled{3} in the display panel 10 of the bendable area BA in the bent state. The fourth point \textcircled{4} may be located between the third point \textcircled{3} and the fifth point \textcircled{5} in the display panel 10 of the bendable area BA in the bent state. In the bendable area BA, the stress at the third point \textcircled{3} is the largest, the stress at each of the second point \textcircled{2} and the fourth point \textcircled{4} is next the largest, and the stress at each of the first point \textcircled{1} and the fifth point \textcircled{5} is the smallest.

However, in the display panel 10 according to an implementation of the present disclosure, as the flexible resin layer SR is disposed therein, the compressive force and the tensile force counteract against each other at each point, particularly, at the third point \textcircled{3} so that the neutral plane that does not receive the stress may act to prevent the occurrence of the bending necking or bending cracks.

Referring to FIG. 4, in the display panel 10 according to an implementation of the present disclosure, in the bendable area BA, the flexible resin layer SR may be disposed on the substrate PI1, ILD, and PI2, a first planarization layer PLN1 may be disposed on the flexible resin layer SR, a plurality of data lines SD2 may be disposed on the first planarization layer PLN1, a second planarization layer PLN2 may be disposed on the plurality of data lines SD2 and the first planarization layer PLN1, and a passivation layer PDL may be disposed on the second planarization layer PLN2. In this regard, the passivation layer PDL may be referred to as an insulating layer. A thickness of the first substrate PI1 may be, for example, 10 micrometers (μm), a thickness of the second substrate PI2 may be 2.0 micrometers (μm), and a thickness of the intermediate layer IDL or IPD may be 0.6 micrometers (μm). A thickness of the first planarization layer PLN1 may be, for example, 2.0 micrometers (μm), a thickness of the second planarization layer PLN2 may be 1.7 micrometers (μm), and a thickness of the passivation layer PDL may be 2.5 micrometers (μm). A thickness of the bendable protective layer 34 may be, for example, 60 micrometers (μm). A thickness of each of the plurality of data lines SD 2 may be, for example, 0.5 micrometers (μm).

In the bendable area BA, each of a real neutral plane RNP and a target neutral plane TNP which does not receive stress because compressive force and tensile force counteract against each other therein may be located in the second planarization layer PLN2.

In some scenarios, the bendable protective layer 34 is applied to an outer side of the display panel 10 in the bendable area BA for the substrate PI1, ILD, and PI2 and the neutral plane compensation. In this regard, a position of the neutral plane is determined based on the thickness and a modulus of the bendable protective layer 34.

When the modulus of the substrate PI1, ILD, and PI2 is lowered or the thickness thereof is reduced, the neutral plane may be positioned in a favorable manner to bending as much as possible. However, the substrate should be protected.

According to some implementations of the present disclosure, the bendable protective layer 34 is not implemented in the bendable area BA of the display panel 10.

In some scenarios, the target neutral plane TNP should be positioned in the second planarization layer PLN2 in the bendable area BA of the display panel 10 in the bent state. However, due to the presence of the bendable protective layer 34 in the display panel 10, the real neutral plane RNP is instead positioned in the second substrate PI2.

As such, in the display panel 10 according to an implementation of the present disclosure, the flexible resin layer SR is disposed between the second substrate PI2 and the first planarization layer PLN1, and the dual substrate PI1 and PI2 acts as a separation layer in terms of the neutral plane, so that the positions of the real neutral plane RNP and the target neutral plane TNP are substantially the same as each other and are positioned in the second planarization layer PLN2 (weak compressed stress).

The position of each of the real neutral plane RNP and the target neutral plane TNP may be adjusted based on the flexible resin layer SR disposed on the substrate PI1, ILD, and PI2 in the bendable area BA in the bent state. In the second planarization layer PLN 2, the real neutral plane RNP may be located on top of the target neutral plane TNP.

The position of the real neutral plane RNP may be changed to a position in the second planarization layer PLN 2 in which the target neutral plane TNP is positioned, and the bendable protective layer 34 may be deleted without being present on the passivation layer PDL.

Therefore, in the display panel 10 according to an implementation of the present disclosure, in the bendable area BA, the bending necking is not generated, the bending crack is not generated, and the bending curvature (Bend R) may be reduced to 0.1 mm or smaller.

In the display panel 10 according to an implementation of the present disclosure, a second difference G2 between the positions of the target neutral plane TNP and the real neutral plane RNP may be significantly reduced due the presence of the flexible resin layer SR, compared to a first difference G1 between the positions of the target neutral plane TNP and the real neutral plane RNP when the bendable protective layer 34 exists in the related art. In this regard, the modulus of the flexible resin layer SR may be, for example, 100 Mpa or lower. The first difference G1 may be, for example, 9.0 micrometers (μm), and the second difference G2 may be, for example, 0.5 micrometers (μm).

Therefore, since the display panel 10 according to an implementation of the present disclosure includes the flexible resin layer SR in the bendable area BA, the target neutral plane TNP and the real neutral plane RNP are located in the same layer, and thus the occurrence of the bending necking or the bending crack may be prevented because the bending stress is not applied thereto.

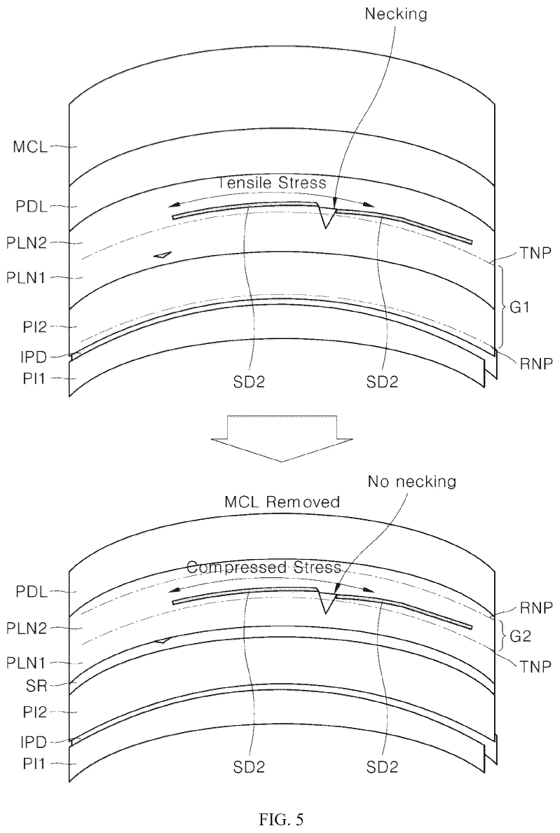

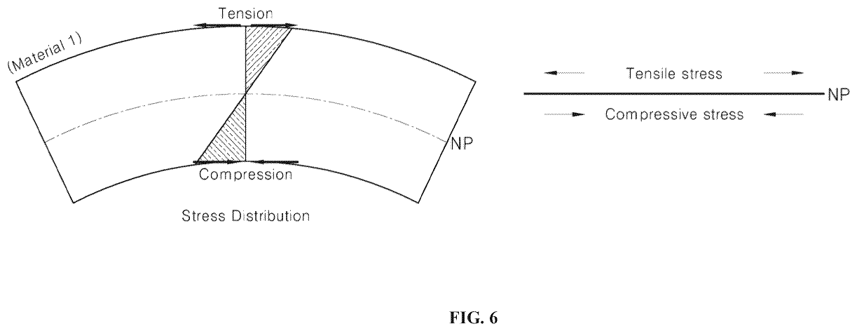

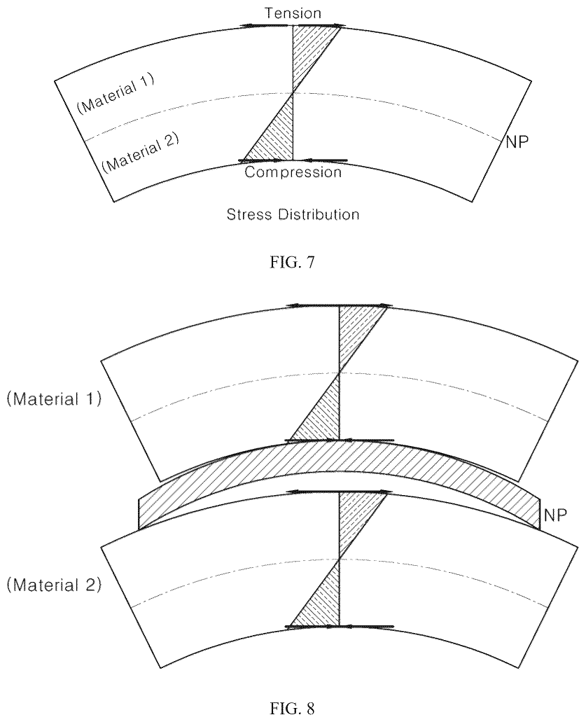

FIG. 5 is an example diagram illustrating the presence or absence of a bending necking based on the presence or absence of a bendable protective layer in a display panel according to an implementation of the present disclosure. FIG. 6 is a diagram illustrating a tensile force, a compressive force, and a neutral plane when one bendable material is made of one material according to an implementation of the present disclosure. FIG. 7 is a diagram illustrating a tensile force, a compressive force, and a neutral plane when one bendable material is made of a plurality of materials according to an implementation of the present disclosure. FIG. 8 is a diagram showing a neutral plane in a case in which a plurality of bendable materials are attached to each other by a flexible material according to an implementation of the present disclosure.

Referring to FIG. 5, in the display panel 10, when the bendable protective layer MCL is present, the target neutral plane TNP is located in the second planarization layer PLN 2 in which the plurality of data lines SD2 are disposed. When the real neutral plane RNP is located in the second substrate PI 2, a tensile stress acts on the second planarization layer PLN 2 to generate a necking of the data line.

In this case, the real neutral plane RNP and the target neutral plane TNP may be located under the plurality of data lines SD2.

In this case, the tensile stress causes the material of the data line SD2 to generate plastic deformation beyond the yield strength of, for example, the material of a combination (Ti/Al/Ti) of titanium and aluminum of the data line SD2 so that a crack occurs in the second planarization layer PLN2 even with a slight external force (including a reliability environment).

However, in the display panel 10 according to an implementation of the present disclosure, as the bendable protective layer MCL is removed and the flexible resin layer SR is disposed on the second substrate PI2, the target neutral plane TNP and the real neutral plane RNP are located in the second substrate PI2, that is, in the same layer.

In this case, in the second planarization layer PLN 2, the real neutral plane RNP may be located on top of the plurality of data lines SD2, and the target neutral plane TNP may be located under the plurality of data lines SD2.

Thus, even when a compressed stress is applied to the second substrate PI2, a necking or a crack does not occur. The compressive stress may be, for example as follows: when the compressive stress applied to the passivation layer PDL is 2.5 pressure, the compressive stress applied to the first planarization layer PLN1 may be 2.0 pressure, and the compressive stress applied to the second planarization layer PLN2 may be 1.7 pressure.

In addition, in the display panel 10 according to an implementation of the present disclosure, as the flexible resin layer SR is disposed therein, the first substrate PI1 and the second substrate PI 2 may be separated from each other from a neutral plane viewpoint.

Accordingly, as the position of the neutral plane is changed, the display panel 10 according to an implementation of the present disclosure may have robust without the necking or crack deformation against an additional external force.

Referring to FIG. 6, the tensile stress is located on top of the neutral plane NP, and the compressive stress is located under the neutral plane NP.

When one bendable material is made of, for example, one material (single physical property; material 1), a central line of an entirety of a thickness of the bendable material in the bent state may be the neutral plane NP. In this case, the tensile force acts on a portion of the bendable material on top of the neutral plane NP, and a compressive force acts on a portion of the bendable material under the neutral plane NP.

Referring to the example of FIG. 7, when one bendable material has a structure of multi-layers made of a plurality of materials (e.g., materials 1 and 2), for example, when the physical properties of the two materials are the same as each other, and the two materials (e.g., materials 1 and 2) are bonded to each other by a hard type resin or an adhesive, the neutral plane (NP) may be located in a central line of the entire thickness of the single bendable material composed of the two materials.

Referring to the example of FIG. 8, when the bendable material (e.g., material 1 and material 2) has a structure of multi-layers made of different materials is attached to each other by the flexible material SR, respective neutral planes may be defined in the two layers made of the different materials. This is a multi-line neutral plane.

The modulus of the flexible material SR may be, for example, 100 Mpa or lower.

In the multi-layer bendable material, the material 2 may not affect the material 1 in terms of the neutral plane.

In the display device 100 according to an implementation of the present disclosure, under the above principle, the flexible resin layer SR is disposed inside the display panel so that both the target neutral plane TNP and the real neutral plane RNP are located in the second planarization layer PLN 2, thus, in the same position, and thus the compression force and the tensile force counteract against each other, thereby preventing the occurrence of bending necking or cracks.

As described above, according to an implementation of the present disclosure, a display device of preventing the line necking or bending cracks from occurring in the bendable area of the display panel during the manufacturing process of the display device may be realized.

In addition, according to an implementation of the present disclosure, the display device may include the flexible resin layer additionally disposed on the substrate in the bendable area BA of the display panel DP, thereby adjusting the position of the neutral plane, thereby preventing the line necking or bending cracks.

Although some implementations of the present disclosure have been described above with reference to the accompanying drawings, the present disclosure may not be limited to some implementations and may be implemented in various different forms. Those of ordinary skill in the technical field to which the present disclosure belongs will be able to appreciate that the present disclosure may be implemented in other specific forms without changing the technical idea or essential features of the present disclosure. Therefore, it should be understood that some implementations as described above are not restrictive but illustrative in all respects.

What is claimed is:

1. A display device comprising:
a substrate including a display area, a non-display area, and a bendable area disposed in the non-display area; and
a display panel disposed on the substrate, wherein the display panel has one side edge that is disposed in the bendable area and is bent in a backward direction to curve back towards the display area with a predetermined curvature,
wherein the display panel includes:
a flexible resin layer disposed on the substrate in the bendable area;
a first planarization layer disposed on the flexible resin layer in the bendable area;
a plurality of data lines disposed on the first planarization layer in the bendable area;
a second planarization layer disposed on the plurality of data lines and the first planarization layer in the bendable area; and
a passivation layer disposed on the second planarization layer in the bendable area,
wherein a real neutral plane and a target neutral plane are positioned in the second planarization layer in the bendable area, wherein in each of the real neutral plane and the target neutral plane, a compressive force and a tensile force counteract against each other.

2. The display device of claim 1, wherein a position of each of the real neutral plane and the target neutral plane is adjusted based on the flexible resin layer disposed on the substrate in the bendable area.

3. The display device of claim 1, wherein a position of the real neutral plane is higher than a position of the target neutral plane in a vertical direction in the second planarization layer.

4. The display device of claim 1, wherein in the second planarization layer, a position of the real neutral plane is higher than positions of each of the plurality of data lines, and a position of the target neutral plane is lower than the positions of each of the plurality of data lines.

5. The display device of claim 1, wherein the display device further comprises first and second back plates disposed on a rear surface of the display panel in the display area.

6. The display device of claim 5, wherein the display panel includes:
a first flat portion;
a second flat portion facing the first flat portion; and
a curved portion positioned between the first flat portion and the second flat portion, wherein the curved portion extends from the first flat portion so as to be bent in the backward direction,
wherein the first and second back plates are respectively disposed on respective rear surfaces of the first and second flat portions.

7. The display device of claim 5, wherein each of the first and second back plates is made of at least one of polyimide (PI), polyethylene naphthalate (PEN), polyethylene terephthalate (PET), and a combination thereof.

8. The display device of claim 5, wherein the display device further comprises:
a fixing member disposed on a rear surface of the first back plate; and
an adhesive member disposed between the fixing member and the second back plate.

9. The display device of claim 8, wherein the fixing member is made of a metal material or includes a composite heat dissipation sheet having a heat blocking function, a grounding function, and a function of protecting a rear surface.

10. The display device of claim 1, wherein the display device further comprises a bendable protective layer disposed on the passivation layer in the bendable area.

11. The display device of claim 10, wherein the bendable protective layer includes a micro coating layer made of a resin-based material.

12. The display device of claim 1, wherein the substrate includes a first substrate, a second substrate and an intermediate layer disposed therebetween.

13. The display device of claim 12, wherein each of the first substrate and the second substrate is made of at least one of polyimide, polyethersulfone, polyethylene terephthalate, and polycarbonate.

14. The display device of claim 12, wherein the intermediate layer includes a single layer or multiple layers made of silicon nitride (SiNx) or silicon oxide (SiOx).

15. The display device of claim 1, wherein in each of the real neutral plane and the target neutral plane, the compressive force and the tensile force counteract against each other such that a stress is not applied to each of the real neutral plane and the target neutral plane.
